(19) United States
(12) Patent Application Publication
(10) Pub. No.: US 2016/0309607 A1
(43) Pub. Date: Oct. 20, 2016

(54) SLIDING MECHANISM WITH FIXING FUNCTION FOR A BLADE SERVER

(71) Applicant: JOCHU TECHNOLOGY CO., LTD., Hsin Chu (TW)

(72) Inventor: Kuo-Ming HSU, Tainan City (TW)

(73) Assignee: JOCHU TECHNOLOGY CO., LTD., Hsin Chu (TW)

(21) Appl. No.: 14/689,416

(22) Filed: Apr. 17, 2015

(51) Int. Cl. H05K 7/14; H05K 7/18

(52) U.S. Cl. CPC H05K 7/1489; H05K 7/183

(57) ABSTRACT

A sliding mechanism includes a slide frame and a resilient plate fixed on the slide frame, has a front section exposed from a front end of the slide frame. A first fixing element mounted on the slide frame, has a protrusion extending outwardly from the front end along a longitudinal direction, wherein the protrusion is constituted by two concentrically disposed cylindrical portions with different diameters. A casing includes a second fixing element having at least one engaging hole with a cross-section adapted to engage the outer periphery of one of the cylindrical portions of the protrusion while the hook unit of the resilient plate engages an end plate of the slide frame, thereby preventing untimely disengagement of an assembly of the slide frame, the resilient plate and the first fixing element from the casing.

### BACKGROUND OF THE INVENTION

1. Field of the Invention

The present invention relates generally to a sliding mechanism, and more particularly to a sliding mechanism with a fixing function by the use of which, a server can be installed conveniently to a PC or a server system and dismantle therefrom, thereby facilitating the repairer or user.

2. The Prior Arts

Generally, a server is mounted slidably to a server system or a computer casing via a sliding mechanism, which is generally inserted into a pair of slide channels in the casing. In case of repairing, the server can be pulled outward from the casing and after the repairing the server is pushed slidably back into the casing. A conventional sliding mechanism used in a server system or a PC generally includes an outer track, an inner track and sometimes an intermediate track between the outer and inner tracks in order to increase a total traveling path of the sliding mechanism. In some cases, the outer tracks are fixed securely to two opposite sides of the casing while the inner tracks are used for carrying the server thereon.

To install a server within a casing, the server is firstly mounted on a pair of inner tracks, which, in turn, are slidably mounted into a pair of outer tracks. Afterward, the outer tracks are inserted slidably into two slide channels formed in the casing. Note that after the outer tracks are inserted fully into the slide channels of the casing, a resilient stick and an engaging hook are used for securely retaining the outer tracks within the casing, thereby preventing untimely removal of the server from the casing.

Note that in order to doubly secure the outer tracks in the slide channels of the casing, in addition to the resilient stick and the engaging hook, presently a position fixing structure is used for securely retaining the outer tracks within the casing. The fixing structure includes a first fixing element mounted at the free ends of the outer tracks and a second fixing element mounted at the free end of the slide channels in the casing, such that when the outer tracks are inserted slidably into the casing and upon reaching the free end of the slide channels, the first and second fixing elements engage each other, thereby preventing untimely removal of the server from the casing.

It is noted that the first fixing element includes a protrusion extending outwardly from the free end of the outer track along a longitudinal direction of the track while the second fixing element includes an engaging hole formed at the free end of the slide channel complementing with the protrusion. Since the protrusion is generally circular or rectangular in cross-section, the engaging hole is also circular or rectangular. In some prior arts, a cylindrical positioning pin is mounted in the engaging hole such that once the outer tracks are slidably inserted into and upon reaching the free end of the slide channels, the circular protrusion extends into the circular hole, or the rectangular protrusion extends into the rectangular hole, or the positioning pin extends into an axial hole formed at the free end of the protrusion, thereby preventing untimely disengagement of the outer tracks from the slide channels.

In case of repairing or replacing a server, the resilient stick is manipulated in such a manner to release engagement between the engaging hook and the casing, thereby permitting outward withdrawal of the outer tracks from the slide channels in the casing, hence the server is exposed to an exterior of the casing for undergoing repairing or replacement. It is noted that in case of a great impact applied on the conventional sliding mechanism at this time, the resilient stick deforms permanently since the stick cannot withstand the great impact. In addition, for a slim server (generally known a blade server), which is relatively compact in size and hence it is also relatively difficult to form the axial hole at the free end of the protrusion mounted on the outer track and the engaging hole at the free end of the slide channel owing to the limited size and their configuration of circular or rectangular and vice versa.

Taiwanese patent publication No. 201446116 and US patent publication No. 2010/0072153 respectively discloses a sliding mechanism consisting of a support frame formed with a rectangular hole and an outer track mounted slidably on the support frame and formed with a rectangular protrusion such that the latter engages in the former once the outer tracks are slidably inserted into the casing, thereby exposing the server from the casing.

Taiwanese patent publication No. 201408241 discloses a slide mechanism including a cylindrical protrusion mounted at the free end of the slide track while a circular engaging hole is formed at the support frame such that upon reaching the free end of the support frame owing to movement of the slide tracks relative to the support frame, the cylindrical protrusion engages the engaging hole, thereby retaining the slide tracks exterior of the support frame.

One drawback of the prior art sliding mechanisms resides in that the different shapes between the cylindrical protrusion and configuration of the engaging hole cannot be matched up and therefore is unsuitable for blade server owing to limited size and space.

### SUMMARY OF THE INVENTION

A primary objective of the present invention is to provide a sliding mechanism with fixing function for a blade server, which consists of circular or rectangular hole and a frame with positioning pin, which is simple in structure, and which is not easily damaged or ruined in case of great impact applied thereto.

One specific feature of the present invention is to provide a resilient plate on the front end of a slide frame and a protrusion extending outwardly from the front end of the slide frame along a longitudinal direction. The resilient plate has a hooking unit exposed from the front end of the slide frame. The protrusion preferably includes a plurality of concentrically disposed cylindrical portions with different diameters. One cylindrical portion has a free end and a positioning hole extending inwardly and axially from the free end. A casing carrying the slide frame is formed an engaging hole or a positioning pin with configuration complementing the cylindrical portion such that once the slide frame slides into the casing, the cylindrical portion extends and engages the engaging hole or the positioning pin extends into the positioning hole in the cylindrical portion, thereby preventing untimely disengagement of an assembly of the slide frame, the resilient plate and the cylindrical portion from the casing also owing to the hooking unit of the resilient plate engaging a lateral side of the slide frame.

A server system or PC with fixing function of the present invention includes a slide mechanism and a casing. The slide mechanism accordingly includes a slide frame having a front end; a resilient plate fixed on the slide frame, having a front section that is exposed from the front end of the slide frame and that is formed a hook unit; and a first fixing element mounted on the front end of the slide frame, having a protrusion extending outwardly from the front end of the slide frame along a longitudinal direction thereof, wherein the protrusion is constituted by a plurality of concentrically disposed cylindrical portions with different diameters. The casing includes a second fixing element having at least one engaging hole with a cross-section so as to adapt to engage the outer periphery of one of the cylindrical portions of the protrusion while the hook unit of the resilient plate engages a lateral side of the slide frame, thereby preventing untimely disengagement of an assembly of the slide frame, the resilient plate and the first fixing element from the casing.

In this embodiment, the protrusion includes a first cylindrical portion and a second cylindrical portion having a diameter smaller than that of the first cylindrical portion. The second cylindrical portion has a free end and a positioning hole extending inwardly and axially from the free end.

Preferably, the engaging hole in the casing is a rectangular hole defining an inner diameter complementing with an outer diameter of the first cylindrical portion such that the latter engages in the former.

Preferably, the engaging hole in the casing is a circular hole defining an inner diameter complementing with an outer diameter of the second cylindrical portion such that the latter engages in the former.

In one embodiment, the second fixing element further includes a positioning pin having an outer diameter complementing with an inner diameter of the positioning hole in the second cylindrical portion such that after the second cylindrical portion engages or align with the annular hole, the positioning pin extends into the positioning hole in the second cylindrical portion so as to enhance engagement between the second cylindrical portion and the casing.

In one embodiment, the first fixing element has two of the protrusions mounted on the front end of the slide frame in a symmetrical manner while the second fixing element has two of the engaging holes formed in the casing for extension of the protrusions respectively therethrough.

Preferably, the casing further includes at least one threaded hole confining the annular hole and a positioning pin such that after the second cylindrical portion engages in the annular hole, the positioning pin is inserted into the axial hole in the second cylindrical portion so as to enhance engagement between the second cylindrical portion and the casing.

In one embodiment, the first fixing element further has a fixing seat formed with two passage holes to permit mounting of the protrusions respectively therein such that the first cylindrical portion and the second cylindrical portion extend respectively through the two passage holes so as to be exposed from a front side of the fixing seat.

Preferably, the first fixing element further includes a fixing plate mounted on a rear side of the fixing seat so as to cover the rear side and a pair of compression springs disposed between the fixing plate and the protrusions so as to bias and expose the first cylindrical portion and the second cylindrical portion from the front side of the fixing seat.

Preferably, the first fixing element further includes two guide rods upon which the compression spring are sleeved thereon so as to align the compression springs to extend in an axial direction of the protrusions.

In the sliding mechanism of the present invention, since the slide frame is secured to an inner wall surface of the casing, by the implementation of the protrusion of the first fixing element and the engaging hole of the second fixing element in the casing, the positioning pin extends into the positioning hole in the cylindrical portion, thereby preventing untimely disengagement of an assembly of the slide frame, the resilient plate and the cylindrical portion from the casing also owing to the hooking unit of the resilient plate engaging a lateral side of the slide frame.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a perspective view of a slide mechanism of the present invention with a fixing function;

FIG. 2 is partly exploded view the slide mechanism of the present invention with the fixing function, illustrating how a first fixing element is mounted on a slide frame;

FIG. 3 shows a cross section view of the first fixing element mounted on a slide frame employed in the slide mechanism of the present invention with fixing function taken along Lines III-III in FIG. 1;

FIG. 4 is a perspective view illustrating how a first cylindrical portion engages one engaging hole in a casing according to the slide mechanism of the present invention;

FIG. 5 is a perspective view illustrating how a second cylindrical portion engages one engaging hole in a casing according to the slide mechanism of the present invention; and

FIG. 6 is a perspective view illustrating how a fastener (positioning) pin extends into a positioning hole in a cylindrical portion when the latter engages one engaging hole in a casing according to the slide mechanism of the present invention.

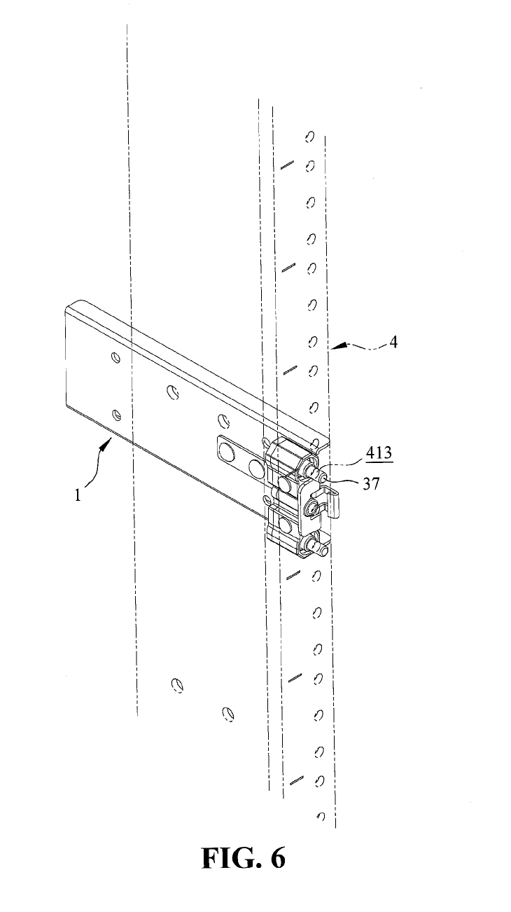

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

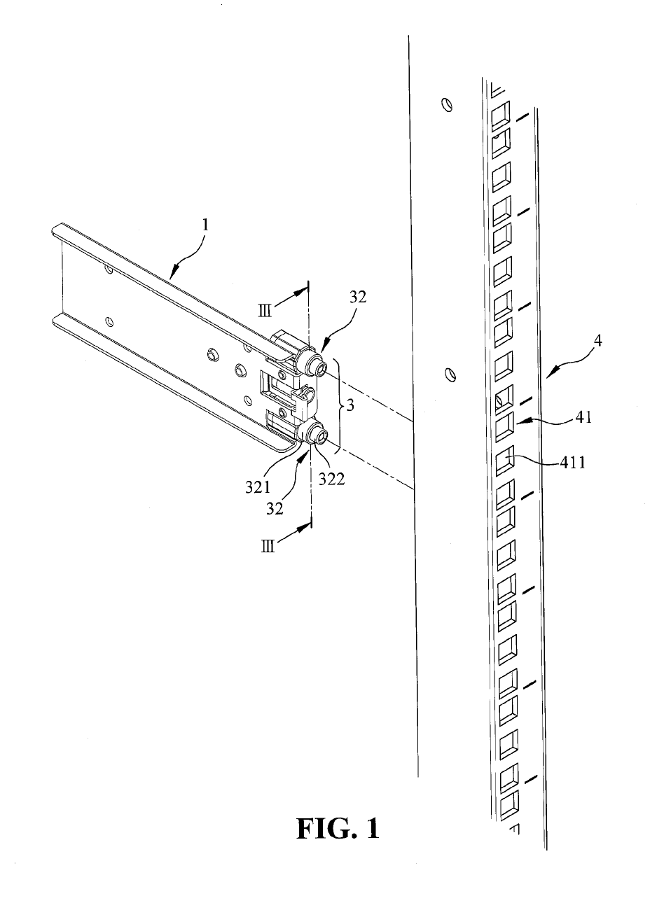

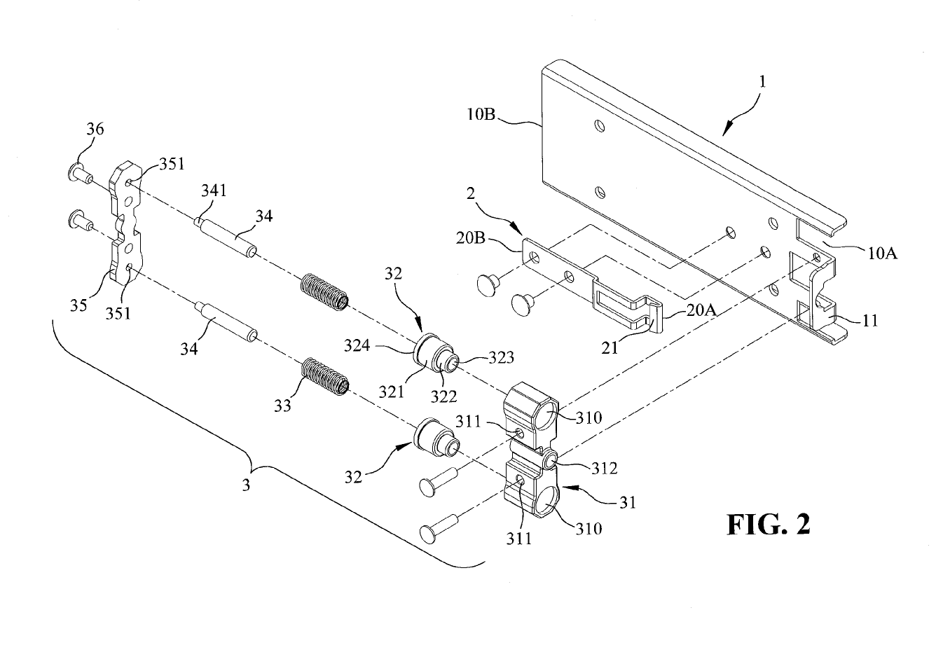

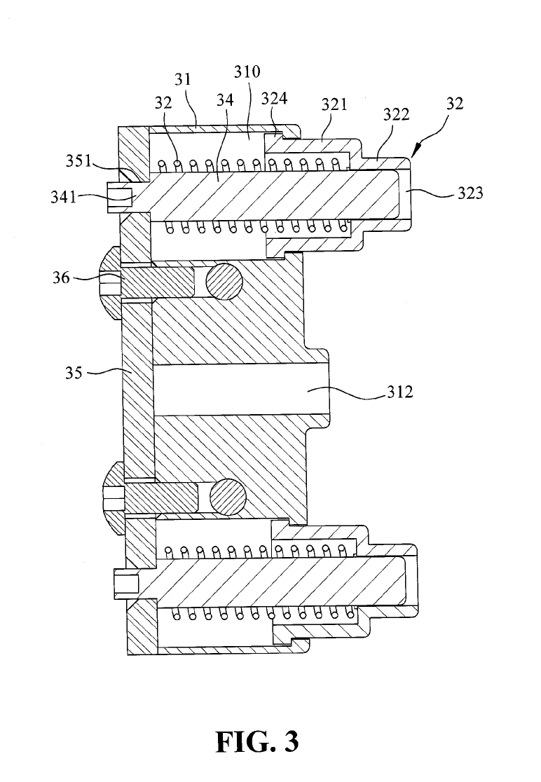

Referring to FIGS. 1-3, wherein FIG. 1 is a perspective view of a server system or PC of the present invention having a slide mechanism with fixing function, with which a slim server (generally known as blade server) can be mounted conveniently in the server system or a computer casing; FIG. 2 is partly exploded view the slide mechanism of the present invention with the fixing function, illustrating how a first fixing element 3 is mounted on a slide frame 1; and FIG. 3 shows a cross section view of the first fixing element 3 mounted on a slide frame employed in the slide mechanism of the present invention with fixing function. As illustrated, the server system accordingly includes a casing 4 and the sliding mechanism. The sliding mechanism includes a slide frame 1; a resilient plate 2; a first fixing element 3 and a second fixing element 41. Preferably in the embodiment, two slide frame 1 serves as one pairs of outer tracks that are mounted slidably and removably in two slide channels formed in two opposite inner side surfaces of the casing 4. The sliding mechanism may further includes inner tracks (not visible) and intermediate tracks (not visible) between the outer and inner tracks in order to increase the traveling path of the server relative to the casing.

As shown in FIG. 2, the slide frame 1 is an elongated frame having opposite front and rear ends 10A, 10B, wherein the front end 10A is bent in such a manner to be an end plate 11. The resilient plate 2 has a rear section 20B fixed by means of rivets on the slide frame 1 such that a front section 20A of the resilient plate is exposed from the front end 10A of the slide frame and is formed a hook unit 21, which in fact is a barbed portion. After assembly, the front section 20A of the resilient plate 2 is swingable relative the slide frame 1 in a direction transverse to a longitudinal direction of the slide frame 1.

Referring again to FIG. 1, the first fixing element 3 is mounted on the front end 10A of the slide frame 1, and has a protrusion 32 extending outwardly from the front end 10A of the slide frame 1 along a longitudinal direction thereof. In this embodiment, the first fixing element 3 has two protrusions 32 mounted on the front end 10A of the slide frame 1 in a symmetrical manner. Each of the protrusions 32 is constituted by a first cylindrical portion 321 and a second cylindrical portion 322 having a diameter different from that of the first cylindrical portion 321. The first cylindrical portion 321 has a rear end and an annular flange 324 extending radially and outwardly from the rear end, the purpose of which will be explained in the following paragraphs. Preferably, the first cylindrical portion 321 and the second cylindrical portion 322 are integrally formed relative to each other.

Referring to FIGS. 2 and 3, the first fixing element 3 further has a fixing seat 31 formed with two passage holes 310 to permit mounting of the protrusions 32 respectively therein such that the first cylindrical portions 321 and the second cylindrical portions 322 extend respectively through the two passage holes 310 so as to be exposed from a front side of the fixing seat 31. At this time, since the annular flanges 324 of the first cylindrical portions 321 engage the peripheries confining the front ends of the passage holes 310, the first cylindrical portion 321 and the second cylindrical portion 322 are prevented from untimely disengagement from the front end of the fixing seat 31. The first fixing element 3 further includes a fixing plate 35 mounted on a rear side of the fixing seat 31, two screws 36 extending threadedly through the screw holes in the fixing plate 35 so as to cover the rear side of the fixing seat 31 and a pair of compression springs 33 disposed between the fixing plate 35 and the protrusions 32 so as to bias and expose the first cylindrical portion 321 and the second cylindrical portion 322 from the front side of the fixing seat 31. The first fixing element 3 further includes two guide rods 34 upon which the compression spring 33 are sleeved thereon so as to align the compression springs 33 to extend in an axial direction of the protrusions 32 and bias the protrusions 32 such that the first cylindrical portions 321 and the second cylindrical portions 322 extend respectively through the two passage holes 310 so as to be exposed from the front side of the fixing seat 31. In case the protrusions 32 are pressed toward the rear end of the slide frame 1, the first and second cylindrical portions 321,322 will retract into the passage holes 310, thereby permitting removal of the fixing seat 31 from the slide frame 1.

To be more specific, each of the guide rods 34 has a constricted rear end extending into a position hole 351 in the fixing plate 35 so as to retain the guide rods 34 stably within the passage holes 310 in the fixing seat 31, which, in turn, align the compression springs 33 to extend in an axial direction of the protrusions 32.

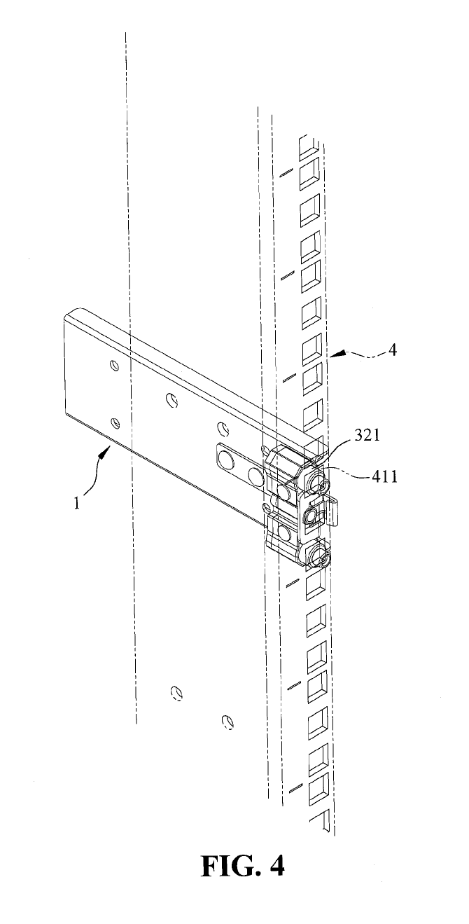

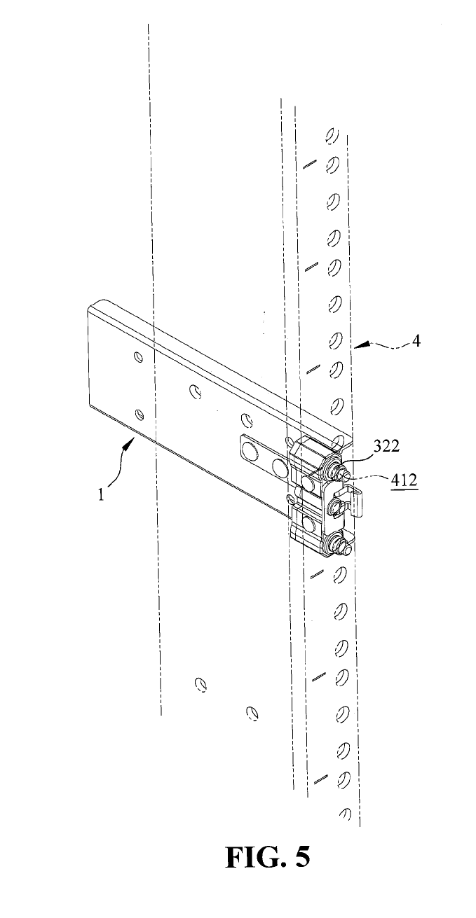

The casing 4 is formed with the second fixing element 41 having two engaging holes 411 align respectively with the protrusions 32 so as to permit extension of one of the cylindrical portions 321, 322 therein while the hook unit 21 of the resilient plate 2 engages the end plate 11 of the slide frame 1, thereby preventing untimely disengagement of an assembly of the slide frame 1, the resilient plate 2 and the first fixing element 3 from the casing 4. Preferably, each of the engaging holes 411 is a rectangular hole as best shown in FIG. 4 or a circular hole as best shown in FIG. 5 complementing with an outer diameter of the first or second cylindrical portion 321, 322 such that the latter engages in the former. Preferably, the second fixing element 41 further includes at least one threaded hole 413 in the casing 4, and a positioning pin 37 is further fastened threadedly in the threaded hole 413 since the positioning pin 37 has outer threads and since it extends axially into the axial hole 323 in the second cylindrical portion 322, thereby enhancing engagement of the positioning pin 37 and the axial hole 323.

For installing a server into the casing 4, the sliding mechanism of the present invention constituted by the above elements are assembled first of all, and after which the assembly of the slide frames 1, the resilient plates 2 and the first fixing elements 3 are installed into the slide channels formed on two inner side surfaces of the casing 4 in a conventional manner such that the front ends 10A of the slide frames 1 are flush with the outer end of the casing 4, wherein, the first cylindrical portion 321 extend into the rectangular hole 411 (see FIG. 4) or the second cylindrical portion 322 extends into the circular hole 412 (see FIG. 5), thereby finishing installation of the server in the casing 4. In case, the positioning pins 37 mounted on the casing 4 in stead of the engaging holes, the positioning pin 37 can be inserted into the positioning hole 323 in the free end of the second cylindrical portion 322 in order to assist engagement of the second cylindrical portion 322 relative to the casing 4. At last, the front end 20A of the resilient plate 2 is manipulated to swing in a direction transverse to a longitudinal length of the slide frame 1 so as to engage the hooking unit 21 on the end plate 11 of the slide frame 1, thereby finishing the installation of the server in the casing 4 and preventing disengagement of the sliding mechanism of the present invention from the casing 4. Sometimes, the assembler may require a fastener screw for serving as the positioning pin in order to facilitate engagement of the second cylindrical portion 322 relative to the casing 4.

In case of repairing or replacing the server, the user only needs to swing the resilient plate 2 in the transverse direction relative to the longitudinal direction of the slide frame 1 in order to disengage the hooking unit 21 from the end plate 11 of the slide frame 1, after which the protrusion 32 is pushed against biasing action of the spring 33 to disengage the respective cylindrical portion 321(322) from the engaging hole in the casing 4. The assembly of the slide frame 1, the resilient plate 2 and the first fixing element 3 can be easily removed from the casing 4. Of course, sometimes the positioning pin 37 is removed first of all from the positioning hole 323 in the second cylindrical portion 322.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A sliding mechanism with fixing function for a server, comprising:
a slide frame having a front end;
a resilient plate fixed on said slide frame, having a front section that is exposed from said front end of said slide frame and that is formed a hook unit;
a first fixing element mounted on said front end of said slide frame, having a protrusion extending outwardly from said front end of said slide frame along a longitudinal direction thereof, wherein said protrusion is constituted by a plurality of concentrically disposed cylindrical portions with different diameters; and
a casing including a second fixing element having at least one engaging hole with a cross-section adapted to engage the outer periphery of one of said cylindrical portions of said protrusion while said hook unit of said resilient plate engages a lateral side of said slide frame, thereby preventing untimely disengagement of an assembly of said slide frame, said resilient plate and said first fixing element from said casing.

2. The sliding mechanism according to claim 1, wherein said cylindrical portions of said protrusion include a first cylindrical portion and a second cylindrical portion having a diameter smaller than that of said first cylindrical portion, said second cylindrical portion having a free end and a positioning hole extending axially and inwardly from said free end.

3. The sliding mechanism according to claim 2, wherein said engaging hole in said casing is a rectangular hole defining an inner diameter complementing with an outer diameter of said first cylindrical portion such that the latter engages in the former.

4. The sliding mechanism according to claim 2, wherein said engaging hole in said casing is a circular hole defining an inner diameter complementing with an outer diameter of said second cylindrical portion such that the latter engages in the former.

5. The sliding mechanism according to claim 2, wherein said second fixing element further includes at least one threaded hole in stead of the engaging hole, in which a positioning pin is further fastened threadedly in the threaded hole.

6. The sliding mechanism according to claim 1, wherein said first fixing element 3 has two of said protrusion mounted on said front end of said slide frame in a symmetrical manner, said second fixing element having two of said engaging holes in said casing for extension of said protrusions respectively therethrough.

7. The sliding mechanism according to claim 6, wherein said first fixing element further includes a fixing seat formed with two passage holes to permit mounting of said protrusions respectively therein such that said first cylindrical portion and said second cylindrical portion extend through a respective one of said two passage holes so as to be exposed from a front side of said fixing seat.

8. The sliding mechanism according to claim 7, wherein said first fixing element further includes a fixing plate mounted on a rear side of said fixing seat so as to cover said rear side and a pair of compression springs disposed between said fixing plate and said protrusions so as to bias and expose said first cylindrical portion and said second cylindrical portion from said front side of said fixing seat.

9. The sliding mechanism according to claim 8, wherein said first fixing element further includes two guide rods upon which said compression spring are sleeved thereon so as to align said compression springs to extend in an axial direction of said protrusions.
